(19) United States
(12) Patent Application Publication
(10) Pub. No.: US 2025/0246417 A1
(43) Pub. Date: Jul. 31, 2025

(54) PLASMA PURGE METHOD AND PLASMA PROCESSING APPARATUS

(71) Applicant: Tokyo Electron Limited, Tokyo (JP)

(72) Inventors: Hideomi HANE, Yamanashi (JP); Ryutaro HARA, Yamanashi (JP); Noriaki FUKIAGE, Yamanashi (JP)

(21) Appl. No.: 19/022,101

(22) Filed: Jan. 15, 2025

(30) Foreign Application Priority Data
Jan. 25, 2024 (JP) 2024-009339

(51) Int. Cl. H01J 37/32

(52) U.S. Cl. CPC H01J 37/32862; H01J 37/3244; H01J 37/32192

(57) ABSTRACT

A plasma purge method performed after cleaning an inside of a processing chamber and before accommodating a substrate inside the processing chamber and performing a substrate processing. The plasma purge method includes (A) activating and supplying a first process gas including N₂ into the processing chamber, and (B) activating and supplying a second process gas including H₂ and O₂ into the processing chamber. Raising and lowering a pressure inside the processing chamber is repeated in each of (A) and (B).

### CROSS-REFERENCE TO RELATED APPLICATIONS

This application is based upon and claims priority to Japanese Patent Application No. 2024-009339, filed on Jan. 25, 2024, the entire contents of which are incorporated herein by reference.

### BACKGROUND

### 1. Field of the Invention

The present disclosure relates to plasma purge methods and plasma processing apparatuses.

### 2. Description of the Related Art

In order to reduce metal contamination compounds (aluminum fluoride: AlF₃ or the like) generated during a chamber cleaning process, Japanese Laid-Open Patent Publication No. 2022-49557 proposes a plasma purge method which activates nitrogen (N₂) gas and supplies the activated N₂ gas to remove the metal contamination from the processing chamber. Further, this plasma purge method activates hydrogen (H₂) gas and oxygen (O₂) gas and supplies the activated H₂ gas and activated O₂ gas to remove metal particles present on components inside the processing chamber through reduction or oxidation reactions, thereby reducing the metal contamination.

### SUMMARY

One aspect of the present disclosure provides a technique capable of sufficiently reducing metal contamination even in a case where a cleaning process of a processing chamber is performed a plurality of times.

According to one aspect of the present disclosure, a plasma purge method includes (A) activating and supplying a first process gas including N₂ into the processing chamber; and (B) activating and supplying a second process gas including H₂ and O₂ into the processing chamber, wherein raising and lowering of a pressure inside the processing chamber is repeated in each of (A) and (B).

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a schematic vertical sectional view illustrating an example of a plasma processing apparatus for performing a plasma purge method according to an embodiment;

FIG. 2 is a schematic plan view of the plasma processing apparatus illustrated in FIG. 1;

FIG. 3 is a bottom view of a gas supply and exhaust unit provided in the plasma processing apparatus illustrated in FIG. 1;

FIG. 4 is a flow chart illustrating a processing flow of the plasma purge method;

FIG. 5 is a diagram for explaining a mechanism by which metal contamination occurs;

FIG. 6 is a diagram for explaining a mechanism by which the metal contamination is reduced;

FIG. 7 is a timing chart illustrating a change in pressure inside a vacuum chamber with time according to the plasma purge method;

FIG. 8 is a diagram illustrating a distribution of plasma emission intensity; and

FIG. 9 is a diagram illustrating a change in Al contamination when a plasma purge method of a reference example is repeated, and a change in Al contamination when the plasma purge method according to the embodiment is performed.

### DETAILED DESCRIPTION

Hereinafter, embodiments for implementing the present disclosure will be described with reference to the drawings. In the drawings, the same components are designated by the same reference numerals, and a redundant description thereof may be omitted.

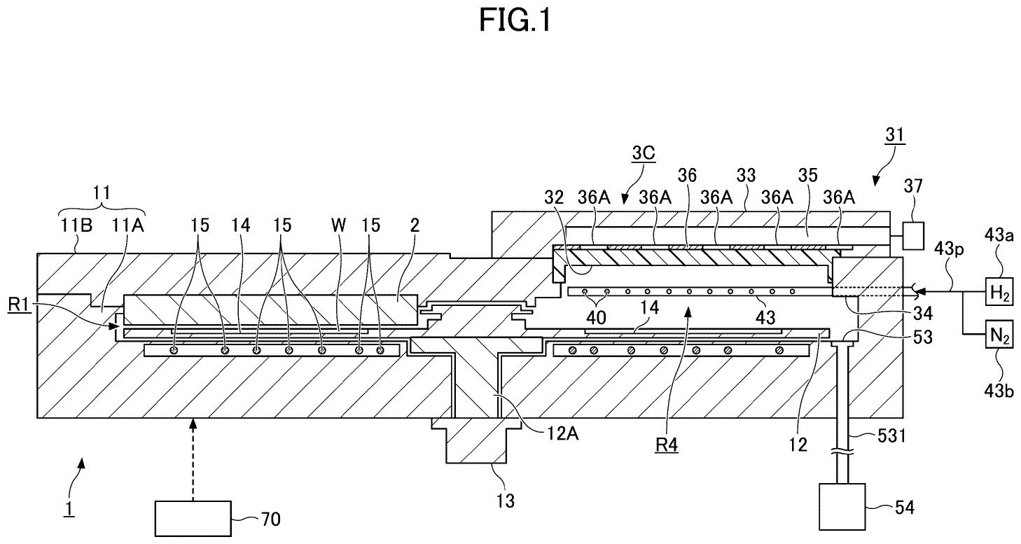

First, a plasma processing apparatus 1 for performing a plasma purge method according to an embodiment will be described, with reference to FIG. 1 through FIG. 3. The plasma processing apparatus 1 is configured as a film forming apparatus (or a deposition apparatus) that deposits (or forms) a desired film on a surface of a substrate, using atomic layer deposition (ALD) or molecular layer deposition (MLD). The substrate is a semiconductor wafer (hereinafter referred to as “a wafer W”), for example. A depression pattern, such as a trench, a via, or the like may be formed on the surface of the wafer W. The plasma processing apparatus 1 is not limited to the deposition apparatus (or the film forming apparatus), and may be an etching apparatus, an ashing apparatus, or the like, for example.

The plasma processing apparatus 1 includes a vacuum chamber (or a processing chamber) 11 that accommodates the wafer W therein and performs a substrate processing on the wafer W in a state where the pressure is reduced to a vacuum atmosphere. The vacuum chamber 11 has a substantially circular planar shape. The vacuum chamber 11 includes a chamber body 11A and a top plate 11B. The chamber body 11A constitutes a sidewall and a bottom of the vacuum chamber 11. The vacuum chamber 11 is hermetically sealed between the chamber body 11A and the top plate 11B via a sealing member, such as an O-ring or the like, for example. The chamber body 11A and the top plate 11B are formed of aluminum (Al), for example.

A turntable 12 is provided inside the vacuum chamber 11. The turntable 12 has a circular planar shape. The turntable 12 is made of quartz, for example. The turntable 12 is supported at a center of a back surface thereof by a support 12A, and is provided horizontally. A rotation mechanism 13 is connected to a lower surface of the support 12A. The rotation mechanism 13 rotates the turntable 12 around a vertical axis via the support 12A during a film forming process (or a deposition process).

A plurality of (six) recesses 14 are provided at an upper surface of the turntable 12 along a circumferential direction (or a rotation direction) of the turntable 12. A wafer W is placed in each of the recesses 14. That is, a plurality of wafers W placed on the turntable 12 are revolve as the turntable 12 rotates.

A plurality of heaters 15 are provided at the bottom of the vacuum chamber 11. The plurality of heaters 15 are arranged concentrically, for example. The plurality of heaters 15 heat the wafers W placed on the turntable 12.

A transfer port 16 for loading and unloading the wafer W is formed in the sidewall of the vacuum chamber 11. The transfer port 16 of the vacuum chamber 11 is opened and closed by a gate valve (not illustrated). When the gate valve is open, the wafer W is loaded into or unloaded from the vacuum chamber 11 by a transfer arm (not illustrated) provided outside the vacuum chamber 11. On the other hand, when the gate valve is closed, an internal space of the vacuum chamber 11 is hermetically sealed.

The plasma processing apparatus 1 includes a gas supply and exhaust unit 2 configured to supply a process gas into the vacuum chamber 11 and to exhaust the gas from the vacuum chamber 11.

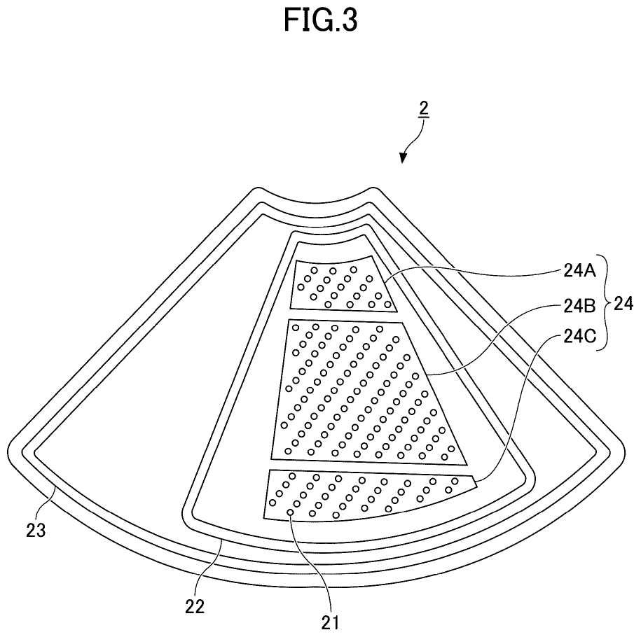

The gas supply and exhaust unit 2 includes a gas discharge port for supplying a silicon-containing gas (Si-containing gas) during a substrate processing (a film forming process or a deposition process) of each wafer W, and an exhaust port. Hereinafter, the gas supply and exhaust unit 2 will be described by also referring to FIG. 3. In a plan view, the gas supply and exhaust unit 2 is formed in a fan shape, which widens in the circumferential direction of the turntable 12, from a center portion toward an outer periphery in a radial direction of the turntable 12. A lower surface of the gas supply and exhaust unit 2 is adjacent to and opposes the upper surface of the turntable 12.

Gas discharge ports 21, an exhaust port 22, and a purge gas discharge port 23 open at the lower surface of the gas supply and exhaust unit 2. A large number of gas discharge ports 21 are arranged in a fan shaped region 24 located on an inner side of a peripheral edge of the gas supply and exhaust unit 2 at the lower surface of the gas supply and exhaust unit 2. The gas discharge ports 21 discharge the Si-containing gas, as a source gas, downward in a shower-like manner to spray the Si-containing gas to the entire surface of the wafer W during the substrate processing. The Si-containing gas is a dichlorosilane (DCS) gas, for example.

Three sections 24A, 24B, and 24C are set in the fan shaped region 24, from the center portion toward the outer periphery in the radial direction of the turntable 12. The gas supply and exhaust unit 2 has a plurality of gas flow paths (not illustrated) partitioned from one another so that the Si-containing gas can be supplied independently to the gas discharge ports 21 provided in each of the section 24A, the section 24B, and the section 24C. Each of the gas flow paths is connected to a supply source (not illustrated) of the Si-containing gas via a gas supply device including a valve and a mass flow controller.

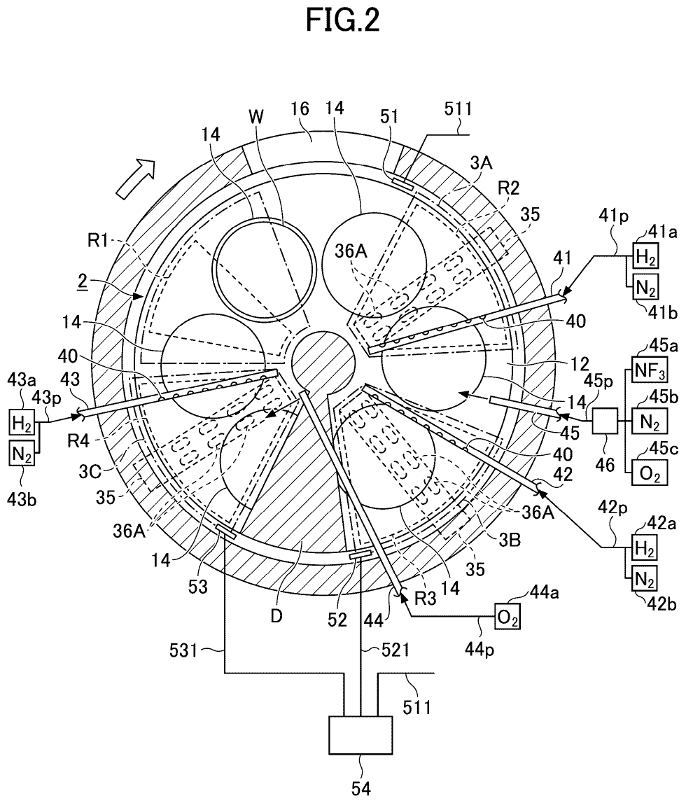

The exhaust port 22 and the purge gas discharge port 23 open at the peripheral edge of the lower surface of the gas supply and exhaust unit 2, toward the upper surface of the turntable 12, in an annular shape surrounding the fan shaped region 24. The purge gas discharge port 23 is located on an outer side of the exhaust port 22. A region on an inner side of the exhaust port 22 on the turntable 12 forms a first processing region R1 (refer to FIG. 2) where the Si-containing gas is supplied to a surface of the wafer W. An exhaust device (not illustrated) is connected to the exhaust port 22, and a supply source of a purge gas is connected to the purge gas discharge port 23. The purge gas is an argon (Ar) gas, for example.

During the film forming process, the plasma processing apparatus 1 simultaneously performs discharging of the Si-containing gas from the gas discharge ports 21, exhausting from the exhaust port 22, and discharging of the purge gas from the purge gas discharge port 23. Accordingly, the Si-containing gas and the purge gas discharged onto the turntable 12 flow from the upper surface of the turntable 12 toward the exhaust port 22, and are exhausted from the exhaust port 22. By performing the discharging and the exhausting of the purge gas in this manner, the first processing region R1 is separated from external atmosphere, and the Si-containing gas can be supplied to the first processing region R1 in a limited manner. That is, it is possible to prevent mixing of the Si-containing gas supplied to the first processing region R1 with each gas and active species of each gas supplied to the outside of the first processing region R1 by plasma formation units 3A through 3C which will be described later.

As illustrated in FIG. 2, the gas supply and exhaust unit 2 includes a second processing region R2, a third processing region R3, and a fourth processing region R4 in this order along the rotation direction of the turntable 12. The gas supply and exhaust unit 2 in the second through fourth processing regions R2 through R4 forms the plasma formation units (or activation units) 3A through 3C capable of activating gases in the second through fourth processing regions R2 through R4, respectively. The plasma formation units 3A through 3C have the same configuration. In the following, the plasma formation unit 3C illustrated in FIG. 1 will be described as the representative plasma formation unit.

The plasma formation unit 3C supplies a gas for plasma formation (or a plasma forming gas) onto the turntable 12, and supplies microwaves to the gas for plasma formation to generate plasma. The plasma formation unit 3C includes an antenna 31 for supplying the microwaves.

The antenna 31 includes a dielectric plate 32 and a metal waveguide 33. In the plan view, the dielectric plate 32 is formed in an approximate fan shape, which widens in the circumferential direction of the turntable 12, from the center portion toward the outer periphery in the radial direction of the turntable 12. An approximately fan shaped through hole is formed in the top plate 11B of the vacuum chamber 11, so as to correspond to the shape of the dielectric plate 32. An inner peripheral surface at a lower end of the through hole slightly protrudes toward the center of the through hole, to form a support portion 34. The dielectric plate 32 is provided to close the through hole from above and to oppose the turntable 12. An outer peripheral edge of the dielectric plate 32 is supported by the support portion 34. The waveguide 33 is provided on the dielectric plate 32. The waveguide 33 includes an inner space 35 extending on the top plate 11B. A slot plate 36 is provided on an upper surface of the dielectric plate 32, so as to make contact with the dielectric plate 32. The slot plate 36 constitutes a lower portion of the waveguide 33. The slot plate 36 has a plurality of slot holes 36A. An end portion of the waveguide 33 at the center portion of the turntable 12 is closed, and a microwave generator 37 is connected to an end portion of the waveguide 33 at a peripheral edge of the turntable 12. The microwave generator 37 supplies microwaves of 2.45 GHZ, for example, to the waveguide 33.

As illustrated in FIG. 2, the second processing region R2 includes a gas injector 41 on a downstream side in the rotation direction of the turntable 12. The gas injector 41 is connected to a hydrogen (H₂) gas supply source 41a and a nitrogen (N₂) gas supply source 41b via a pipe 41p. The gas injector 41 discharges hydrogen gas and nitrogen gas toward the upstream side in the rotation direction of the turntable 12. By supplying the hydrogen gas, H is bonded to a dangling bond in a SiO₂ film, the plasma processing apparatus 1 can reform the film into a dense film.

The third processing region R3 includes a gas injector 42 on the upstream side in the rotation direction of the turntable 12. The gas injector 42 is connected to a hydrogen gas supply source 42a and a nitrogen gas supply source 42b via a pipe 42p. The gas injector 42 discharges the hydrogen gas and the nitrogen gas toward the downstream side in the rotation direction of the turntable 12.

The fourth processing region R4 includes a gas injector 43 on the downstream side in the rotation direction of the turntable 12. The gas injector 43 is connected to a hydrogen gas supply source 43a and a nitrogen gas supply source 43b via a pipe 43p. The gas injector 43 discharges the hydrogen gas and the nitrogen gas toward the upstream side in the rotation direction of the turntable 12. The second through fourth processing regions R2 through R4 may be connected to another gas supply source, such as an argon gas supply source, for example.

Each of the gas injectors 41 through 43 is formed of an elongated tubular body having a closed tip end, for example. The gas injectors 41 through 43 are fixed to the sidewall of the vacuum chamber 11, respectively, and extend horizontally from the sidewall toward the center portion of the vacuum chamber 11. The gas injectors 41 through 43 are arranged to intersect the regions through which the wafer W on the turntable 12 passes, respectively. Each of the gas injectors 41 through 43 has a plurality of discharge ports 40 along an extending direction thereof. For example, the discharge ports 40 of the gas injectors 41 through 43 are formed to overlap the regions where the wafer W on the turntable 12 passes, respectively.

In the example illustrated in FIG. 2, the gas injector 41 is provided below the region that is adjacent to and is on the downstream side of the plasma formation unit 3A in the rotation direction, but may be provided below the plasma formation unit 3A, for example. The gas injector 42 is provided below the region that is adjacent to and is on the upstream side of the plasma formation unit 3B in the rotation direction, but may be provided below the plasma formation unit 3B, for example. The gas injector 43 is provided below the region that is adjacent to and is on the downstream side of the plasma formation unit 3C in the rotation direction, but may be provided below the plasma formation unit 3C, for example.

A gas injector 44 is provided at an end portion of the fourth processing region R4 on the upstream side. The gas injector 44 is connected to an oxygen (O₂) gas supply source 44a via a pipe 44p. The gas injector 44 is formed of an elongated tubular body having a closed tip end. The gas injector 44 is fixed to the sidewall of the vacuum chamber 11, and extends horizontally from the sidewall toward the center portion of the vacuum chamber 11. The gas injector 44 has a gas discharge port (not illustrated) at the tip end thereof. The discharge port discharges the oxygen gas from the center portion of the vacuum chamber 11 toward the outer periphery in the radial direction of the turntable 12. In addition, the gas injector 44 may be connected to another gas supply source (for example, an argon gas supply source).

In the second through fourth processing regions R2 through R4, the microwaves supplied to the waveguide 33 pass through the slot holes 36A of the slot plate 36 to reach the dielectric plate 32, and are supplied to the gases discharged below the dielectric plate 32, such as the hydrogen gas, the nitrogen gas, and the oxygen gas, for example. Thus, limited plasma formation occurs in the second through fourth processing regions R2 through R4 below the dielectric plate 32.

Further, as illustrated in FIG. 2, a gas injector 45 is provided between the second processing region R2 and the third processing region R3. The gas injector 45 is formed by an elongated tubular body having an open tip end. The gas injector 45 is fixed to the sidewall of the vacuum chamber 11, and protrudes a short distance from the sidewall toward the center portion of the vacuum chamber 11. The gas injector 45 discharges various gases from the tip end opening toward the center portion of the vacuum chamber 11.

The gas injector 45 is connected to a nitrogen trifluoride (NF₃) gas supply source 45a, a nitrogen gas supply source 45b, and an oxygen gas supply source 45c via a pipe 45p, for example. A remote plasma source 46 is provided at an intermediate position of the pipe 45p. The remote plasma source 46 activates the various gases, introduced from the respective supply sources to the gas injector 45 via the pipe 45p, by plasma. Thus, the gas injector 45 can discharge various activated gases into the vacuum chamber 11.

For example, during the substrate processing, the gas injector 45 discharges the oxygen gas into the vacuum chamber 11. The plasma processing apparatus 1 may activate the oxygen gas and discharge the activated oxygen gas from the gas injector 45, or may discharge the oxygen gas from the gas injector 45 without activating the oxygen gas.

Moreover, during the cleaning process of the inside of the vacuum chamber 11, for example, the gas injector 45 discharges a fluorine-containing gas, such as a nitrogen trifluoride gas or the like, into the vacuum chamber 11. The plasma processing apparatus 1 may activate the nitrogen trifluoride gas and discharge the activated nitrogen trifluoride gas from the gas injector 45, or may discharge the nitrogen trifluoride gas from the gas injector 45 without activating the nitrogen trifluoride gas. The cleaning process is performed in a case where it is determined that a large amount of oxide film is deposited on the surface of the turntable 12 or on the inside of the vacuum chamber 11 by the repeated substrate processing (or film forming process) and that it is better to remove the oxide film.

Further, in the plasma purge method of the inside of the vacuum chamber 11, for example, the gas injector 45 discharges the nitrogen gas and the oxygen gas into the vacuum chamber 11 at appropriate timings. The plasma processing apparatus 1 may activate the nitrogen gas and discharge the activated nitrogen gas from the gas injector 45, or may discharge the nitrogen gas from the gas injector 45 without activating the nitrogen gas. The cleaning process and the plasma purge method will be described later in more detail.

The vacuum chamber 11 includes a separation region D between the third processing region R3 and the fourth processing region R4. A top surface of the separation region D is lower than top surfaces of the third processing region R3 and the fourth processing region R4. In the plan view, the separation region D is formed in a fan shape, which widens in the circumferential direction of the turntable 12, from the center portion toward the outer periphery in the radial direction of the turntable 12. A lower surface of the separation region D opposes the upper surface of the turntable 12 at a position sufficiently adjacent thereto. A gap between the lower surface of the separation region D and the upper surface of the turntable 12 is set to 3 mm, for example, in order to prevent the gas from entering below the separation region D.

In addition, a first exhaust port 51, a second exhaust port 52, and a third exhaust port 53 open at positions facing an end portion of the second processing region R2 on the upstream side, an end portion of the third processing region R3 on the downstream side, and an end portion of the fourth processing region R4 on the upstream side, respectively, on an outer side of the turntable 12. The first through third exhaust ports 51 through 53 exhaust the gases in the second through fourth processing regions R2 through R4, respectively.

As illustrated in FIG. 1, the third exhaust port 53 is formed in a region on the outer side of the turntable 12 in the chamber body 11A of the vacuum chamber 11. The third exhaust port 53 is located below the turntable 12, and is connected to an exhaust device 54 via an exhaust flow path 531. As illustrated in FIG. 2, the first exhaust port 51 and the second exhaust port 52 have the same configuration as the third exhaust port 53, and for example, are connected to the exhaust device 54 of the gas supply and exhaust unit 2 via exhaust flow paths 511 and 521, respectively. An exhaust amount adjustment unit (not illustrated) is provided in each of the exhaust flow paths 511, 521, and 531. Each exhaust amount adjustment unit can individually adjust the amount of gas exhausted from the first through third exhaust ports 51 through 53 via the exhaust device 54. The exhaust amounts from the first through third exhaust ports 51 through 53 may be adjusted by a common exhaust amount adjustment unit. Accordingly, in the second through fourth processing regions R2 through R4, the gases discharged from the gas injectors 41 through 43 are exhausted from the first through third exhaust ports 51 through 53, respectively, and a vacuum atmosphere having a pressure according to the exhaust amounts is formed in the vacuum chamber 11.

As illustrated in FIG. 1, the plasma processing apparatus 1 includes a controller 70 configured to control various components. The controller 70 may be a computer including a processor, a memory, an input-output interface, a communication interface, or the like, which are not illustrated. The processor is one of or a combination of a central processing unit (CPU), a graphics processing unit (GPU), an application specific integrated circuit (ASIC), a field programmable gate array (FPGA), a circuit including a plurality of discrete semiconductor devices, or the like, and is configured to execute a program stored in the memory. The memory includes a main storage device, such as a semiconductor memory or the like, and an auxiliary storage device, such as a disk, a drive, a semiconductor memory (flash memory) or the like. The memory stores a program, a recipe, or the like for controlling operations of the respective components of the plasma processing apparatus 1 by transmitting control signals to the respective components and performing a substrate processing (or a film forming process) on the wafer W and a cleaning process including a plasma purge method.

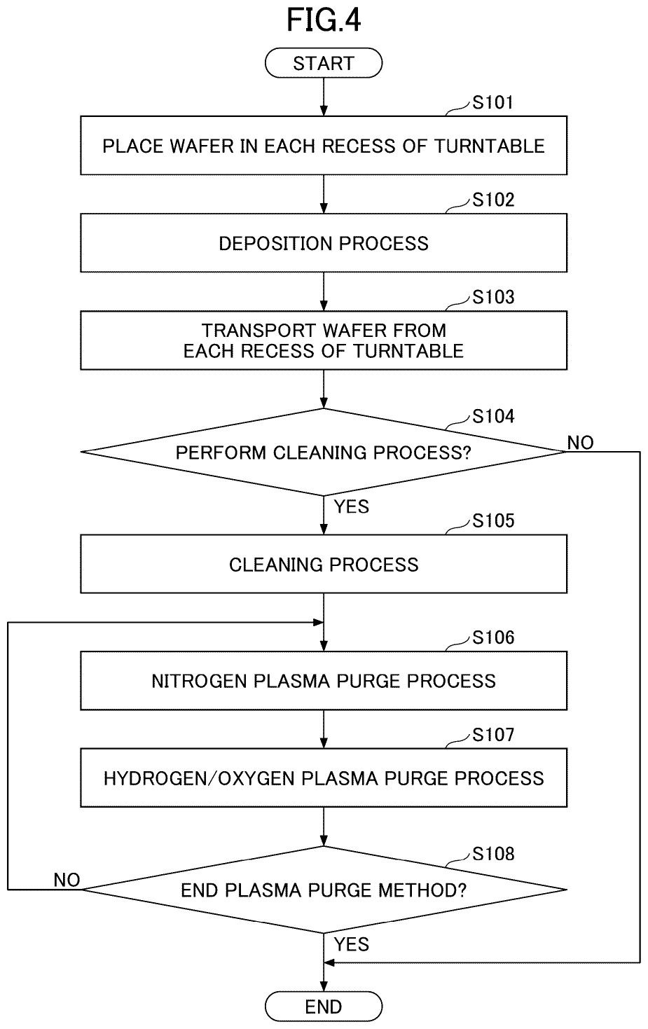

The plasma processing apparatus 1 is basically configured as described above, and next, the substrate processing on each wafer W and the cleaning process will be described with reference to FIG. 4 through FIG. 7.

The controller 70 of the plasma processing apparatus 1 controls the substrate processing and the cleaning process, by the processor thereof executing the program stored in the memory. The controller 70 performs processes of steps S101 through S108 illustrated in FIG. 4 during the substrate processing and the cleaning process.

In order to perform the substrate processing, the plasma processing apparatus 1 opens the transfer port 16 of the vacuum chamber 11, transfers the wafer W into the vacuum chamber 11 in cooperation with the transfer arm, and successively places the wafer W in each of the recesses 14 of the turntable 12 (step S101).

When the wafers W are placed in all of the recesses 14 of the turntable 12, the plasma processing apparatus 1 closes the transfer port 16 of the vacuum chamber 11 and starts the substrate processing (the film forming process or the deposition process) (step S102).

For example, the plasma processing apparatus 1 operates the gas supply and exhaust unit 2 to supply an appropriate gas and exhaust the gas, thereby reducing the pressure inside the vacuum chamber 11 to a vacuum atmosphere. In this case, the plasma processing apparatus 1 controls each gas supply device based on a supply timing and a flow rate of each gas of the recipe, and controls the exhaust amount of gas from the exhaust device 54 based on a pressure of the recipe to adjust the pressure inside the vacuum chamber 11 to a target pressure. In addition, the plasma processing apparatus 1 controls the rotation mechanism 13 based on a target rotational speed of the recipe to rotate the turntable 12. Further, the plasma processing apparatus 1 adjusts a temperature of each wafer W by controlling the heaters 15 based on a target temperature of the recipe. The plasma processing apparatus 1 generates the plasma in the gas inside the vacuum chamber 11 by supplying microwaves to the gas by the plasma formation units 3A through 3C.

The source gas is supplied to each wafer W placed on the turntable 12 rotating inside the vacuum chamber 11 as each wafer W passes through the first processing region R1, and the source gas adheres onto the surface of each wafer W. Further, the source gas adhered to the surface of each wafer W is oxidized and reformed as each wafer W passes through the second through fourth processing regions R2 through R4. The plasma processing apparatus 1 can form a film having a desired film thickness on the surface of each wafer W by continuing the substrate processing described above for a set period.

After the substrate processing, the plasma processing apparatus 1 opens the transfer port 16 of the vacuum chamber 11, and unloads each wafer W placed in each recess 14 of the turntable 12 in cooperation with the transfer arm (step S103).

In addition, after the substrate processing, the controller 70 determines whether or not to perform the cleaning process of the vacuum chamber 11 (step S104). For example, the controller 70 counts a total period of the substrate processing or a number of times the substrate processing is performed, and determines that the cleaning process is to be performed when the total period or the number of times reaches a value greater than or equal to a preset threshold value. The controller 70 proceeds to the process of step S105 in a case where the cleaning process is to be performed (YES in step S104, and ends the current substrate processing in a case where the cleaning process is not to be performed (NO in step S104). Moreover, the plasma processing apparatus 1 repeats the processes of steps S101 through S103 again in a case where a next substrate processing is to be performed.

In step S105, the plasma processing apparatus 1 performs the cleaning process to remove a film deposited on each component inside the vacuum chamber 11 during the substrate processing. For example, the plasma processing apparatus 1 discharges a nitrogen trifluoride gas from the gas injector 45 into the vacuum chamber 11, to dry clean the inside of the vacuum chamber 11. The plasma processing apparatus 1 removes the film deposited on each component by continuing the cleaning process for the set period. The plasma processing apparatus 1 may perform the cleaning process in a state where the wafer W is not placed in each of the recesses 14, or may perform the cleaning process in a state where a dummy wafer or the like is placed in each of the recesses 14.

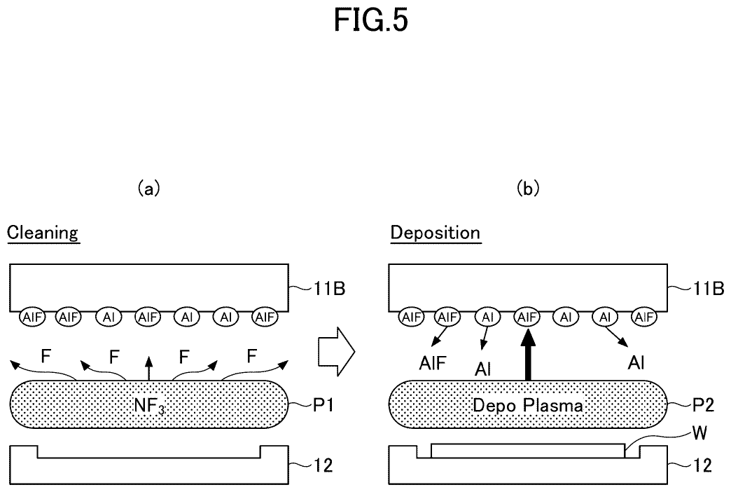

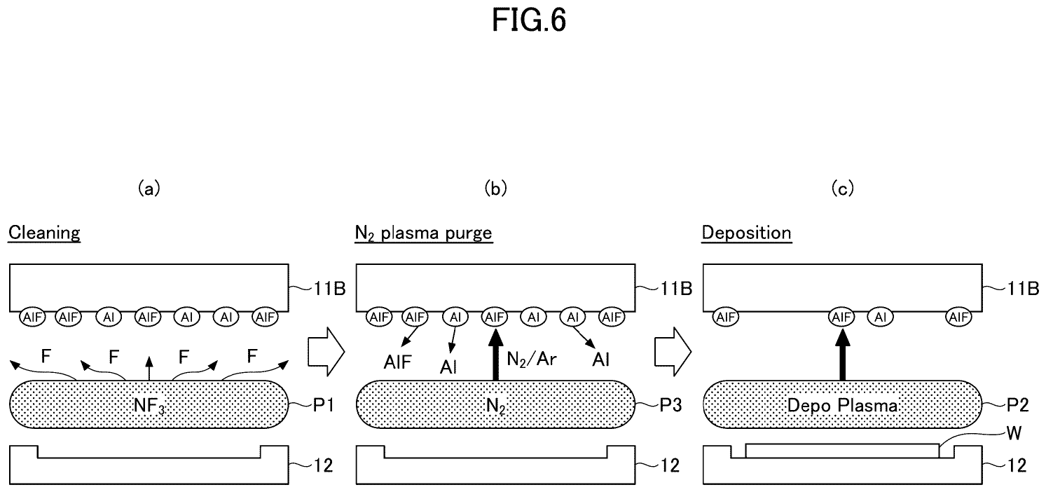

When the plasma processing apparatus 1 performs the cleaning process, metal contaminants are easily generated at (adhered on or separated from) each component or the like inside the vacuum chamber 11. Examples of the metal contaminants include metal particles, such as aluminum fluoride (AlF₃), aluminum (Al), or the like. For example, as illustrated in part (a) of FIG. 5 and part (a) of FIG. 6, Al, which is the material used for the chamber body 11A and the top plate 11B, is etched by plasma P1 formed during the cleaning process, thereby generating aluminum fluoride which adheres onto the lower surface of the top plate 11B. As illustrated in part (b) of FIG. 5, in the case where the substrate processing (film forming process) is performed after the cleaning process, the aluminum separates from the lower surface of the top plate 11B due to plasma P2 formed during the substrate processing, and the separated aluminum adheres onto the wafer W as particles.

For this reason, the plasma processing apparatus 1 performs the plasma purge method after the cleaning process and before the substrate processing is performed on the wafer W (before loading the wafer W into the vacuum chamber 11). That is, the plasma purge method in step S106 and subsequent steps is performed in a state where the wafer W is not placed in each of the recesses 14 of the turntable 12.

In the plasma purge method, the plasma processing apparatus 1 first performs a nitrogen plasma purge process (step S106: process (A)). During the nitrogen gas plasma purge process, a first process gas including nitrogen gas (N₂) is supplied into the vacuum chamber 11 from the gas injectors 41 through 43 and 45. A flow rate of the nitrogen gas is in a range of approximately 200 sccm to approximately 250 sccm, for example. In this state, the plasma processing apparatus 1 supplies the microwaves from the plasma formation units 3A through 3C to the nitrogen gas, to decompose and activate the nitrogen gas. An output of the microwave generator 37 in this case is approximately 2.5 kW, for example.

Further, the plasma processing apparatus 1 sets the temperature of the heaters 15 to 550° C., for example.

The nitrogen gas activated in the nitrogen plasma purge process (nitrogen plasma) sputters aluminum fluoride, which is a metal contamination substance generated by the cleaning process, as illustrated part (b) of FIG. 6. That is, the aluminum fluoride separates from the lower surface of the top plate 11B by the sputter effect, and is exhausted from the inside of the vacuum chamber 11 under the suction of the exhaust device 54. By performing the nitrogen plasma purge process in this manner, the plasma processing apparatus 1 can remove the metal contaminants which cause the particles during the film forming process. As illustrated in part (c) of FIG. 6, the plasma processing apparatus 1 can prevent the separation of aluminum from the lower surface of the top plate 11B by the plasma P2 formed during the substrate processing after the cleaning process, and can avoid the adhesion of the particles onto the wafer W.

In the plasma purge method, the plasma processing apparatus 1 next performs a hydrogen and oxygen plasma purge process (step S107: process (B)). In the hydrogen and oxygen plasma purge process (hereinafter also referred to as a “hydrogen/oxygen plasma purge process”), the plasma processing apparatus 1 supplies hydrogen radicals and oxygen radicals into the vacuum chamber 11. Specifically, the plasma processing apparatus 1 supplies hydrogen gas into the vacuum chamber 11 from the gas injectors 41 through 43, and supplies oxygen gas into the vacuum chamber 11 from the gas injectors 44 and 45. A flow rate of the hydrogen gas is approximately 4 standard liters per minute (slm), for example. A flow rate of the oxygen gas is approximately 6 slm, for example. In this state, the plasma processing apparatus 1 supplies the microwaves to the hydrogen gas and the oxygen gas from the plasma formation units 3A through 3C, and decomposes and activates the hydrogen gas and the oxygen gas, to generate hydrogen radicals and oxygen radicals. The output of the microwave generator 37 in this case is approximately 3.0 kW, for example. In addition, the plasma processing apparatus 1 sets the temperature of the heaters 15 to 550° C., for example.

During the hydrogen/oxygen plasma purge process, hydrogen radicals H* functioning as a reducing agent and oxygen radicals O* functioning as an oxidizing agent are generated, thereby generating various reactions. The metal element of the component inside the vacuum chamber 11 is extracted by a reduction reaction of the reducing agent or an oxidation reaction of the oxidizing agent. That is, the hydrogen radicals H* and the oxygen radicals O* can remove not only the metal particles present on the surface of the component, but also the metal particles located slightly on an inner side the surface and separated from the component, by the reduction reaction or by the oxidation reaction. Although such reduction reaction and oxidation reaction are not necessarily effective in reducing the metal contamination for all metal elements, because particles of various kinds of metal elements are present inside the vacuum chamber 11, a metal element for which the reduction reaction or the oxidation reaction is effective in reducing the metal contamination is always included in the various kinds of metal elements. The plasma processing apparatus 1 can reduce the metal contamination of a metal element for which the supply of the reducing agent and the oxidizing agent is effective in reducing the metal contamination, by supplying the hydrogen radicals H* and the oxygen radicals O*.

When the nitrogen plasma purge process (step S106) and the hydrogen/oxygen plasma purge process (step S107) are performed successively, the controller 70 determines whether or not to end the plasma purge method (step S108). For example, the controller 70 holds in advance a target number of times steps S106 and S107 are to be repeated according to a recipe or the like, and in a case where the target number of times is not reached (NO in step S108), the controller 70 returns the process to step S106 and repeats the same processing flow thereafter. On the other hand, in a case where the number of times steps S106 and S107 are repeated reaches the target number of times (YES in step S108), the controller 70 ends the plasma purge method.

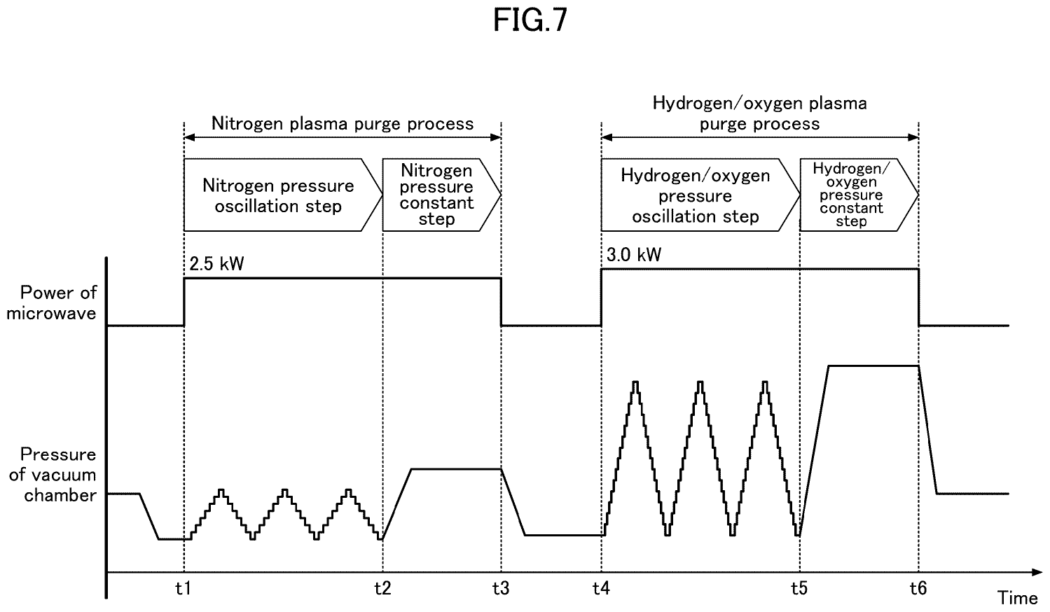

As described above, according to the plasma purge method, the metal contamination substance inside the vacuum chamber 11 can be reduced significantly by performing the nitrogen plasma purge process and the hydrogen/oxygen plasma purge process. However, when the cleaning process is repeated in the related art, the amount of metal contamination substance remaining on the chamber body 11A and the top plate 11B tends to gradually increase. Hence, in the plasma purge method according to the embodiment, the pressure inside the vacuum chamber 11 is varied during the nitrogen plasma purge process and the hydrogen/oxygen plasma purge process, so as to vary a light emission distribution of the plasma formed inside the vacuum chamber 11. The operation of varying the pressure and the effects thereof will be described below with reference to FIG. 7.

The controller 70 oscillates the pressure by varying the exhaust amount of the gas from the exhaust device 54 (or the exhaust amount adjustment unit) during each of the nitrogen plasma purge process and the hydrogen/oxygen plasma purge process.

Specifically, the nitrogen plasma purge process includes a nitrogen pressure oscillation process (or step) and a nitrogen pressure constant process (or step). For example, the controller 70 performs the nitrogen pressure oscillation process and the nitrogen pressure constant process in this order during one nitrogen plasma purge process.

During the nitrogen pressure oscillation process, the controller 70 sets an upper limit value and a lower limit value of the pressure for the nitrogen pressure oscillation process, and increases and decreases the pressure inside the vacuum chamber 11 within the range of the set upper limit value and lower limit value. The controller 70 sets the upper limit value of the nitrogen pressure oscillation process to 1.0 Torr (133 Pa) and sets the lower limit value of the nitrogen pressure oscillation process to 0.4 Torr (53 Pa), for example, based on parameters stored in the recipe or the like.

In the nitrogen pressure oscillation process, the controller 70 varies the exhaust amount of the exhaust device 54 while maintaining the supply amount of the nitrogen gas constant, to oscillate the pressure inside the vacuum chamber 11 between the set upper limit value and lower limit value. In this state, the controller 70 instructs (transmits) the target exhaust amount to the exhaust device 54 in a stepwise manner. Thus, the pressure inside the vacuum chamber 11 increases and decreases stepwise, according to the stepwise variation of the exhaust gas amount. The stepwise increase or decrease of the pressure refers to a pressure increase or decrease that occurs in distinct levels, stages, or steps, in contrast to a continuous pressure increase or decrease.

Further, during the nitrogen pressure oscillation process, the controller 70 repeats the oscillation of the pressure inside the vacuum chamber 11 a plurality of times for a target period of the nitrogen pressure oscillation process. The target period of the nitrogen pressure oscillation process can be set arbitrarily by the user, and can be set to 90 minutes, for example. In FIG. 7, the increase and decrease of the pressure inside the vacuum chamber 11 during the target period is repeated three times, but the number of times the pressure is oscillated is not particularly limited, and may be four times or more, for example. After performing the nitrogen pressure oscillation process for the target period thereof, the controller 70 proceeds to a next nitrogen pressure constant process.

During the nitrogen pressure constant process, the controller 70 maintains the pressure inside the vacuum chamber 11 constant by maintaining the supply amount of the nitrogen gas and the exhaust amount of the exhaust device 54 constant. The pressure inside the vacuum chamber 11 during the nitrogen pressure constant process is preferably higher than the upper limit value of the pressure during the nitrogen pressure oscillation process. The controller 70 sets the pressure inside the vacuum chamber 11 to 2.3 Torr (307 Pa), for example, based on the parameters stored in the recipe or the like. In addition, the controller 70 continues the nitrogen pressure constant process for a target period of the nitrogen pressure constant process. The target period of the nitrogen pressure constant process may be shorter than the period of the nitrogen pressure oscillation process, and may be set to 30 minutes, for example. When the nitrogen pressure constant process is performed for the target period thereof, the controller 70 stops the supply of the nitrogen gas and reduces the pressure inside the vacuum chamber 11, to end the nitrogen plasma purge process.

The next hydrogen/oxygen plasma purge process also includes a hydrogen and oxygen pressure oscillation process (hereinafter also referred to as a “hydrogen/oxygen pressure oscillation process”) and a hydrogen and oxygen pressure constant process (hereinafter also referred to as a “hydrogen/oxygen pressure constant process”), similar to the nitrogen plasma purge process. For example, the controller 70 performs the hydrogen/oxygen pressure oscillation process and the hydrogen/oxygen pressure constant process in this order during one hydrogen/oxygen plasma purge process.

During the hydrogen/oxygen pressure oscillation process, the controller 70 sets an upper limit value and a lower limit value of the pressure for the hydrogen/oxygen pressure oscillation process, and increases and decreases the pressure inside the vacuum chamber 11 within the range between the set upper limit value and lower limit value. The upper limit value of the pressure for the hydrogen/oxygen pressure oscillation process may be set higher than or equal to the upper limit value of the pressure for the nitrogen pressure oscillation process. Further, the lower limit value of the pressure for the hydrogen/oxygen pressure oscillation process may be set higher than or equal to the lower limit value of the pressure for the nitrogen pressure oscillation process. The controller 70 sets the upper limit value of the hydrogen/oxygen pressure oscillation process to 3.0 Torr (400 Pa), and sets the lower limit value of the hydrogen/oxygen pressure oscillation process to 0.5 Torr (67 Pa), for example. In other words, the pressure oscillation during the hydrogen/oxygen pressure oscillation process is greater than the pressure oscillation during the nitrogen pressure oscillation process.

During the hydrogen/oxygen pressure oscillation process, the controller 70 varies the exhaust amount of the exhaust device 54 while maintaining the supply amount of the hydrogen gas and the oxygen gas constant, to oscillate the pressure inside the vacuum chamber 11 between the set upper limit value and lower limit value. Further, the controller 70 instructs (transmits) the target exhaust amount to the exhaust device 54 in a stepwise manner also during the hydrogen/oxygen pressure oscillation process. Thus, the pressure inside the vacuum chamber 11 increases and decreases stepwise, according to the stepwise variation of the exhaust gas amount.

Further, during the hydrogen/oxygen pressure oscillation process, the controller 70 repeats the oscillation of the pressure inside the vacuum chamber 11 a plurality of times for a target period of the hydrogen/oxygen pressure oscillation process. The target period of the hydrogen/oxygen pressure oscillation process may be set to 90 minutes, for example. After performing the hydrogen/oxygen pressure oscillation process for the target period thereof, the controller 70 proceeds to the a hydrogen/oxygen pressure constant process.

During the hydrogen/oxygen pressure constant process, the controller 70 maintains the pressure inside the vacuum chamber 11 constant by maintaining the supply amount of hydrogen gas, the supply amount of oxygen gas, and the exhaust amount of the exhaust device 54 constant. The pressure inside the vacuum chamber 11 during the hydrogen/oxygen pressure constant process is preferably higher than the upper limit value of the pressure during the hydrogen/oxygen pressure oscillation process. The controller 70 sets the vacuum chamber 11 to 4.4 Torr (587 Pa), for example, based on parameters stored in the recipe or the like. The controller 70 continues the hydrogen/oxygen pressure constant process for the target period of the hydrogen/oxygen pressure constant process. The target period of the hydrogen/oxygen pressure constant process may be shorter than the period of the hydrogen/oxygen pressure oscillation process, and may be set to 30 minutes, for example. When the controller 70 performs the hydrogen/oxygen pressure constant process for the target period thereof, the controller 70 lowers the pressure inside the vacuum chamber 11 and ends the hydrogen/oxygen plasma purge process.

A sequence of the plasma purge method including the nitrogen pressure oscillation process and the hydrogen/oxygen pressure oscillation process described above can be summarized as follows.

In the plasma purge method, the nitrogen plasma purge process is started at a time point in time t1 after the cleaning process. When the plasma purge process is started, the controller 70 first performs the nitrogen pressure oscillation process. The plasma processing apparatus 1 supplies the nitrogen gas into the vacuum chamber 11 and exhausts the gas inside the vacuum chamber 11 from the exhaust device 54. The plasma processing apparatus 1 generates the plasma of the nitrogen gas inside the vacuum chamber 11, by supplying the nitrogen gas and supplying the microwaves.

After the point in time t1, the plasma processing apparatus 1 increases the pressure inside the vacuum chamber 11 from the lower limit value to the upper limit value, and oscillates the pressure between the upper limit value and the lower limit value. The plasma processing apparatus 1 repeats the oscillation of the pressure inside the vacuum chamber 11 for a period from the point in time t1 to a point in time t2 (the target period of the nitrogen pressure oscillation process).

At the point in time t2, the plasma processing apparatus 1 ends the nitrogen pressure oscillation process, and moves on to the nitrogen pressure constant process. In the nitrogen pressure constant process, the plasma processing apparatus 1 exhausts the gas at a constant exhaust rate from the exhaust device 54, while supplying the nitrogen gas. In addition, the plasma processing apparatus 1 generates plasma in the nitrogen gas inside the vacuum chamber 11, to perform a plasma purge of the vacuum chamber 11 in which the pressure is constant at a high pressure. The plasma processing apparatus 1 maintains the constant pressure inside the vacuum chamber 11 for a period from the point in time t2 to a point in time t3 (the target period of the nitrogen pressure constant process).

When the point in time t3 is reached, the plasma processing apparatus 1 ends the nitrogen plasma purge process. In this state, the plasma processing apparatus 1 stops the supply of the nitrogen gas, to reduce the pressure inside the vacuum chamber 11.

Thereafter, at a point in time t4, the plasma processing apparatus 1 starts the hydrogen/oxygen plasma purge process. When the hydrogen/oxygen plasma purge process is started, the controller 70 first performs the hydrogen/oxygen pressure oscillation process. The plasma processing apparatus 1 supplies hydrogen gas and oxygen gas into the vacuum chamber 11, and exhausts the gas inside the vacuum chamber 11 from the exhaust device 54. In addition, the plasma processing apparatus 1 supplies the hydrogen gas and the oxygen gas and supplies the microwaves, to generate plasma of the hydrogen gas and the oxygen gas inside the vacuum chamber 11.

After a point in time t4, the plasma processing apparatus 1 varies the exhaust amount of the gas while supplying the hydrogen gas and the oxygen gas to the vacuum chamber 11, to increase the pressure inside the vacuum chamber 11 from the lower limit value to the upper limit value, and oscillate the pressure between the upper limit value and the lower limit value. The plasma processing apparatus 1 repeats the oscillation of the pressure inside the vacuum chamber 11 for a period from the point in time t4 to a point in time t5 (the target period of the hydrogen/oxygen pressure oscillation process).

At the point in time t5, the plasma processing apparatus 1 ends the hydrogen/oxygen pressure oscillation process, and moves on to the hydrogen/oxygen pressure constant process. During the hydrogen/oxygen pressure constant process, the plasma processing apparatus 1 exhausts the gas at a constant exhaust amount from the exhaust device 54, while supplying the hydrogen gas and the oxygen gas. The plasma processing apparatus 1 generates plasma in the hydrogen gas and the oxygen gas inside the vacuum chamber 11, to perform a plasma purge of the vacuum chamber 11 in which the pressure is constant at a high pressure. The plasma processing apparatus 1 maintains the constant pressure inside the vacuum chamber 11 for a period from the point in time t5 to a point in time t6 (the target period of the constant hydrogen/oxygen pressure process).

As described above, in the plasma purge method, the pressure inside the vacuum chamber 11 is increased and decreased in a state where plasmas of nitrogen gas, hydrogen gas, and oxygen gas are generated. Thus, the plasma purge method can vary an in-plane distribution of the plasma emission intensity according to the pressure variation inside the vacuum chamber 11. In other words, the plasmas of the nitrogen gas, the hydrogen gas, and the oxygen gas spread throughout the inside of the vacuum chamber 11, and can act on the metal contamination substance adhered to each component of the vacuum chamber 11. As a result, it is possible to reduce the amount of metal contamination substance remaining on the components of the vacuum chamber 11.

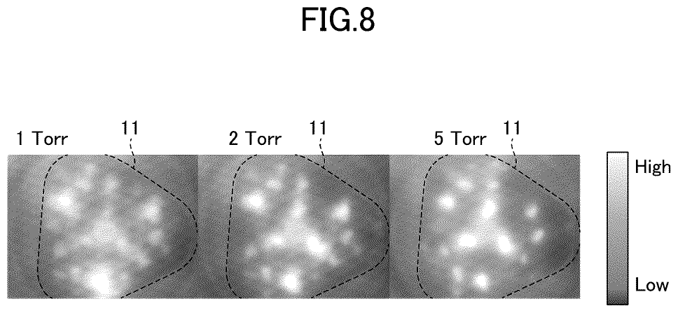

Hereinafter, results of evaluating the distribution of the plasma emission intensity when the plasma of the hydrogen gas is generated inside the vacuum chamber 11, using an infrared camera installed outside the vacuum chamber 11, will be described with reference to FIG. 8. A left part of FIG. 8 illustrates the results for a case where the pressure inside the vacuum chamber 11 is 1 Torr (133 Pa). A middle part of FIG. 8 illustrates the results for a case where the pressure inside the vacuum chamber 11 is 2 Torr (267 Pa). A right part of FIG. 8 illustrates the results for a case where the pressure inside the vacuum chamber 11 is 5 Torr (667 Pa). In FIG. 8, the lighter the image, the higher the plasma emission intensity is, and the darker the image, the lower the plasma emission intensity is.

As illustrated in FIG. 8, it can be seen that the distribution of the plasma emission intensity of the hydrogen gas varies by varying the pressure inside the vacuum chamber 11. Specifically, in the case where the pressure inside the vacuum chamber 11 is low, the plasma emission intensity at an outer peripheral portion of the vacuum chamber 11 becomes high. On the other hand, in the case where the pressure inside the vacuum chamber 11 is high, the plasma emission intensity at a center portion of the vacuum chamber 11 becomes high. Accordingly, it may be regarded that the in-plane distribution of the plasma emission intensity can be varied by oscillating the pressure inside the vacuum chamber 11.

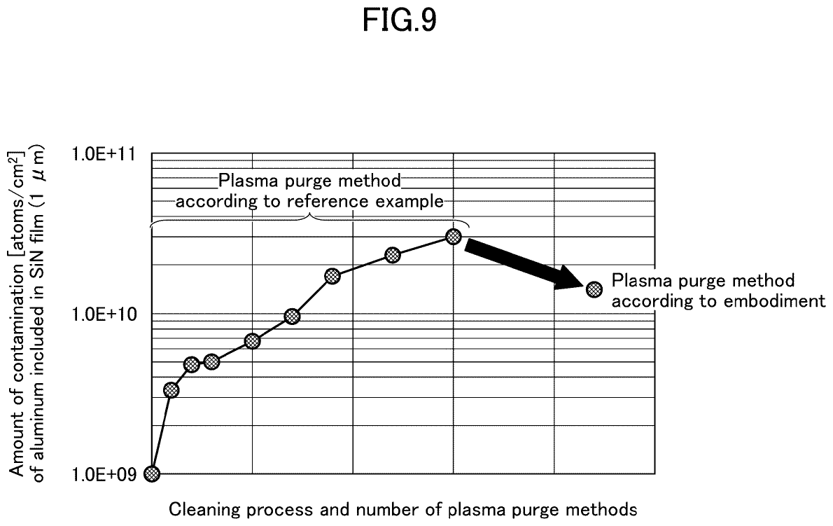

Finally, a relationship between the variation in the pressure inside the vacuum chamber 11 and the reduction of the metal contamination will be described with reference to FIG. 9. FIG. 9 illustrates amounts of aluminum contamination for a case where the plasma purge method of a reference example in which the pressure inside the vacuum chamber 11 is not varied is performed after the cleaning process, and the plasma purge method according to the embodiment in which the pressure inside the vacuum chamber 11 is varied is performed thereafter. The amount of aluminum contamination refers to a detected amount of aluminum mixed in a SiN film formed on the wafer W, and corresponds to an index indicating an amount of aluminum fluoride which is the metal contamination substance generated inside the vacuum chamber 11.

When the plasma purge method according to the reference example in which the pressure inside the vacuum chamber 11 is not varied is performed, as illustrated in a graph of the reference example, the aluminum contamination gradually increases as the number of times the plasma purge method is performed increases. The plasma purge method according to the embodiment in which the pressure inside the vacuum chamber 11 is varied is performed once with respect to the vacuum chamber 11 in which the aluminum contamination increased (refer to the plasma purge method according to the embodiment illustrated in the graph). By performing the plasma purge method according to the embodiment once, it was possible to reduce the aluminum contamination which increased in the reference example. That is, it may be regarded that the plasma purge method which varies the pressure inside the vacuum chamber 11 effectively acts to reduce the metal contamination substance inside the vacuum chamber 11, and that the amount of aluminum contaminants can be reduced. That is, in the plasma purge method according to the embodiment, it may be regarded that the metal contamination substance of the vacuum chamber 11 can be reduced, and even when the cleaning process is repeated a plurality of times, the effect of reducing the metal contamination substance can be maintained.

The plasma purge method and the plasma processing apparatus 1 according to the embodiment are not limited to those described above, and various modifications may be made. For example, the plasma purge method is not limited to varying the pressure inside the vacuum chamber 11 stepwise during the nitrogen pressure oscillation process or the hydrogen/oxygen pressure oscillation process, and may be configured to vary the pressure linearly (continuously). Further, for example, in the plasma purge method, the method of activating the nitrogen gas, the hydrogen gas, and the oxygen gas is not particularly limited, and the gases may be heated without using plasma.

The plasma purge method may be configured to perform the nitrogen plasma purge process and the hydrogen/oxygen plasma purge process only once. In this case, the metal contamination of the vacuum chamber 11 can be reduced by adjusting the target periods of the nitrogen pressure oscillation process and the hydrogen/oxygen pressure oscillation process. In addition, the plasma purge method may not perform (or omit) the nitrogen pressure constant process and the hydrogen/oxygen pressure constant process. Thus, the period of performing the plasma purge method can be shortened. Further, the plasma purge method may be performed in a reverse order, that is, in an order of the nitrogen plasma purge process and the hydrogen/oxygen plasma purge process.

The plasma processing apparatus 1 is not limited to the configuration described above, and may be an apparatus in which the turntable 12 revolves while rotating each of the wafers W (on its axis) placed in each of the recesses 14 of the turntable 12. Further, the plasma processing apparatus 1 may be a single wafer type apparatus that successively processes the wafers W one by one, or may be a batch type apparatus that simultaneously processes a plurality of wafers W that are arranged in a single batch.

The technical concepts and effects of the present disclosure described in the embodiments will be described below.

A first aspect of the present disclosure is a plasma purge method including the steps of (A) activating and supplying a first process gas including N₂ into the processing chamber; and (B) activating and supplying a second process gas including H₂ and O₂ into the processing chamber, wherein raising and lowering of a pressure inside the processing chamber is repeated in each of the steps (A) and (B). The steps (A) and (B) may be performed after cleaning an inside of a processing chamber (vacuum chamber 11) and before accommodating a substrate (wafer W) inside the processing chamber to perform a substrate processing.

According to the plasma purge method of the first aspect described above, by repeating the raising and lowering of the pressure inside the processing chamber (vacuum chamber 11), the location where the metal contamination substance is removed inside the processing chamber can be varied, and the metal contamination can be uniformly removed. For this reason, the plasma purge method can effectively reduce the metal contamination even in the case where the cleaning process with respect to the inside of the processing chamber is repeated a plurality of times.

Further, in the plasma purge method, the raising of the pressure inside the processing chamber (the vacuum chamber 11) may increase the pressure stepwise, and the lowering of the pressure inside the processing chamber may decrease the pressure stepwise. In this case, the plasma purge method can increase and decrease the pressure inside the processing chamber at an appropriate speed, and can stably remove the metal contamination substance at each level of the stepwise pressure variation.

The pressure oscillation in the step (B) may be larger than the pressure oscillation in the step (A). In this case, in the plasma purge method, a reduction reaction or an oxidation reaction can be generated in a wide range inside the processing chamber (the vacuum chamber 11) during the processing using the second process gas, and metal particles present on various components can be removed satisfactorily.

In addition, each of the steps (A) and (B) may include maintaining the pressure inside the processing chamber (the vacuum chamber 11) constant after repeating the raising and lowering of the pressure inside the processing chamber. In this case, the plasma purge method can perform sputtering, a reduction reaction, and an oxidation reaction even in a state where the pressure inside the processing chamber is stabilized, and can more effectively reduce the metal contamination substance.

Further, the repeating the raising and lowering of the pressure inside the processing chamber (the vacuum chamber 11) may be performed for a period longer than a period of the maintaining the pressure inside the processing chamber constant. In this case, the plasma purge method can increase the amount of metal contamination substance that is removed, and shorten a period of the plasma purge method.

In the plasma purge method, the steps (A) and (B) may be performed in this order. In this case, even if the metal contamination substance is generated inside the processing chamber (the vacuum chamber 11) during the step (A), the plasma purge method can satisfactorily remove the metal contamination substance during the step (B).

In the plasma purge method, the step (A) and the step (B) may be performed a plurality of times. In this case, the plasma purge method can more reliably remove the metal contamination substance inside the processing chamber.

In addition, the first process gas and the second process gas may be activated by plasma. By using such first process gas and second process gas that are activated by plasma, the plasma purge method can efficiently remove the metal contamination substance.

Further, a power of microwave for generating the plasma in the step (B) may be greater than a power of the microwave for generating the plasma in the step (A). In this case, the plasma purge method can cause a sufficient reduction reaction and oxidation reaction inside the processing chamber (vacuum chamber 11).

Moreover, according to a second aspect of the present disclosure, a plasma processing apparatus 1 includes a processing chamber (the vacuum chamber 11) configured to accommodate a substrate (the wafer W) therein and perform a substrate processing on the substrate; a gas supply and exhaust unit (the gas supply and exhaust unit 2) configured to supply a first process gas including N₂ and a second process gas including H₂ and O₂ into the processing chamber, and exhaust gases inside the processing chamber; an activation unit configured to activate the first process gas and the second process gas; and a controller 70 configured to control the gas supply and exhaust unit and the activation unit to perform a process including the steps of (A) activating and supplying the first process gas including N₂ into the processing chamber; (B) activating and supplying the second process gas including H₂ and O₂ into the processing chamber; and (C) repeating raising and lowering a pressure inside the processing chamber in each of the steps (A) and (B). The controller 70 may perform the steps (A) and (B) of the process after cleaning an inside of the processing chamber and before accommodating the substrate inside the processing chamber to perform the substrate processing. Accordingly, the plasma processing apparatus 1 can effectively prevent the metal contamination, even in a case where the cleaning process is repeated a plurality of times.

While certain embodiments of the plasma purge method and the plasma processing apparatus 1 have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

The plasma processing apparatus of the present disclosure may be applied to any type of apparatuses, such as an atomic layer deposition (ALD) apparatus, a capacitively coupled plasma (CCP) apparatus, an inductively coupled plasma (ICP) apparatus, a radial line slot antenna (RLSA) apparatus, an electron cyclotron resonance plasma (ECR) apparatus, and a helicon wave plasma (HWP) apparatus.

According to one aspect of the present disclosure, the metal contamination can be sufficiently reduced even in the case where the cleaning process of the processing chamber is performed a plurality of times.

What is claimed is:

1. A plasma purge method comprising:
(A) activating and supplying a first process gas including N₂ into a processing chamber; and
(B) activating and supplying a second process gas including H₂ and O₂ into the processing chamber,
wherein raising and lowering of a pressure inside the processing chamber is repeated in each of (A) and (B).

2. The plasma purge method as claimed in claim 1, wherein:
the raising of the pressure inside the processing chamber increases the pressure stepwise, and
the lowering of the pressure inside the processing chamber decreases the pressure stepwise.

3. The plasma purge method as claimed in claim 2, wherein a pressure oscillation in (B) is larger than a pressure oscillation in (A).

4. The plasma purge method as claimed in claim 1, wherein each of (A) and (B) includes maintaining the pressure inside the processing chamber constant after repeating the raising and lowering of the pressure inside the processing chamber.

5. The plasma purge method as claimed in claim 4, wherein the repeating the raising and lowering of the pressure inside the processing chamber is performed for a period longer than a period of the maintaining the pressure inside the processing chamber constant.

6. The plasma purge method as claimed in claim 1, wherein (A) and (B) are performed in this order.

7. The plasma purge method as claimed in claim 1, wherein (A) and (B) are performed a plurality of times.

8. The plasma purge method as claimed in claim 1, wherein the first process gas and the second process gas are activated by plasma.

9. The plasma purge method as claimed in claim 8, wherein a power of microwave for generating the plasma in (B) is greater than a power of the microwave for generating the plasma in (A).

10. The plasma purge method as claimed in claim 1, wherein (A) and (B) are performed after cleaning an inside of the processing chamber and before accommodating a substrate inside the processing chamber to perform a substrate processing.

11. A plasma processing apparatus comprising:
a processing chamber configured to accommodate a substrate therein and perform a substrate processing on the substrate;
a gas supply and exhaust unit configured to supply a first process gas including N₂ and a second process gas including H₂ and O₂ into the processing chamber, and exhaust gases inside the processing chamber;
an activation unit configured to activate the first process gas and the second process gas; and
a controller configured to control the gas supply and exhaust unit and the activation unit to perform a process including:
(A) activating and supplying the first process gas including N₂ into the processing chamber;
(B) activating and supplying the second process gas including H₂ and O₂ into the processing chamber; and
(C) repeating raising and lowering of a pressure inside the processing chamber in each of (A) and (B).

12. The plasma processing apparatus as claimed in claim 11, wherein the controller is configured to perform (A) and (B) of the process after cleaning an inside of the processing chamber and before accommodating the substrate inside the processing chamber to perform the substrate processing.
